(19) United States
(12) Patent Application Publication
(10) Pub. No.: US 2024/0081041 A1
(43) Pub. Date: Mar. 7, 2024

(54) SEMICONDUCTOR STRUCTURE AND METHOD FOR FORMING SAME

(71) Applicant: CHANGXIN MEMORY TECHNOLOGIES, INC., Hefei City (CN)

(72) Inventors: Daohuan FENG, Hefei (CN); Xiaojie Li, Hefei (CN)

(21) Appl. No.: 18/449,771

(22) Filed: Aug. 15, 2023

Related U.S. Application Data
(63) Continuation of application No. PCT/CN2022/129920, filed on Nov. 4, 2022.

(30) Foreign Application Priority Data
Sep. 1, 2022 (CN) 202211066753.3

(51) Int. Cl. H10B 12/00

(52) U.S. Cl. CPC H10B 12/30; H10B 12/03; H10B 12/05

(57) ABSTRACT

A semiconductor structure includes a substrate and a stack structure located on the substrate. The stack structure includes a plurality of memory units arranged at intervals in a first direction. Each memory unit includes a transistor structure. The transistor structure includes an active structure and a gate layer. At least part of the active structure is distributed around a periphery of part of the gate layer, and the projection of the active structure on a top surface of the substrate is in the shape of a U which opens toward a second direction. Both the first direction and the second direction are parallel to the top surface of the substrate, and the first direction intersects with the second direction. A method for forming the semiconductor structure is also provided.

### CROSS-REFERENCE TO RELATED APPLICATIONS

The present application is a U.S. continuation application of International Application No. PCT/CN2022/129920, filed on Nov. 4, 2022, which claims priority to Chinese Patent Application No. 202211066753.3, filed on Sep. 1, 2022. International Application No. PCT/CN2022/129920 and Chinese Patent Application No. 202211066753.3 are incorporated herein by reference in their entireties.

### BACKGROUND

A dynamic random access memory (DRAM) is a semiconductor device commonly used in electronic devices such as computers. It is composed of a plurality of memory units. Each of the memory units usually includes a transistor and a capacitor. A gate of the transistor is electrically connected to a word line, a source of the transistor is electrically connected to a bit line, and a drain of the transistor is electrically connected to the capacitor. The transistor can be controlled to be on or off by a word line voltage applied on the word line. As a result, data information stored in the capacitor can be read or data information can be written into the capacitor via the bit line.

In order to meet the requirements of continuously shrinking size and increasing storage density of semiconductor structures such as DRAM, the semiconductor structures such as DRAM that have a three-dimensional structure came into being. However, the semiconductor structures such as DRAM that have the three-dimensional structure still have some shortcomings such as a poor control capability on the gate of the transistor and high power consumption, which restrict a further improvement of the performance of the semiconductor structures.

Therefore, how to improve the control capability on the gate of the semiconductor structure and reduce the power consumption of the semiconductor structures is an urgent technical problem to be solved at present.

### SUMMARY

A semiconductor structure and a method for forming the same provided by some embodiments of the disclosure are intended for improving the control capability on the gate of the semiconductor structure and reducing power consumption of the semiconductor structure, thereby improving the performance of the semiconductor structure.

According to some embodiments, the disclosure provides a semiconductor structure including:
a substrate; and
a stack structure located on the substrate, the stack structure including a plurality of memory units arranged at intervals in a first direction, each of the plurality of memory units including a transistor structure, the transistor structure including an active structure and a gate layer, at least part of the active structure being distributed around a periphery of part of the gate layer, a projection of the active structure on a top surface of the substrate being in a shape of a U which opens toward a second direction, in which both the first direction and the second direction are parallel to the top surface of the substrate, and the first direction intersects with the second direction.

According to other embodiments, the disclosure also provides a method for forming a semiconductor structure, including the following operations:
providing a substrate;
forming a stack on the substrate, in which the stack includes a plurality of memory regions arranged at intervals in a first direction, in which the first direction is parallel to a top surface of the substrate; and
forming a memory unit including a transistor structure in each of the plurality of memory regions, in which the transistor structure includes an active structure and a gate layer, at least part of the active structure is distributed around a periphery of part of the gate layer, and a projection of the active structure on the top surface of the substrate is in a shape of a U which opens toward a second direction, in which the first direction and the second direction are both parallel to the top surface of the substrate, and the first direction intersects with the second direction.

### BRIEF DESCRIPTION OF THE DRAWINGS

FIG. 1 is a schematic structural top view of a semiconductor structure in an embodiment of the disclosure;

FIG. 2 is a schematic cross-sectional diagram at position a-a of FIG. 1;

FIG. 3 is a schematic cross-sectional diagram at position b-b of FIG. 1;

FIG. 4 is a schematic cross-sectional diagram at position c-c of FIG. 1;

FIG. 5 is a schematic cross-sectional diagram at position d-d of FIG. 1;

FIG. 6A and FIG. 6B are schematic three-dimensional structural diagrams of a memory unit in an embodiment of the disclosure;

FIG. 7 is a flowchart of a method for forming a semiconductor structure in an embodiment of the disclosure; and

FIG. 8 to FIG. 22 are schematic structural diagrams corresponding to main operations during forming a semiconductor structure according to an embodiment of the disclosure.

### DETAILED DESCRIPTION

Embodiments of the semiconductor structure and the method for forming it provided in the disclosure will be described in detail below with reference to the accompanying drawings.

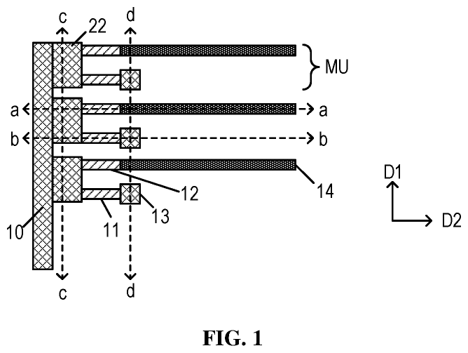

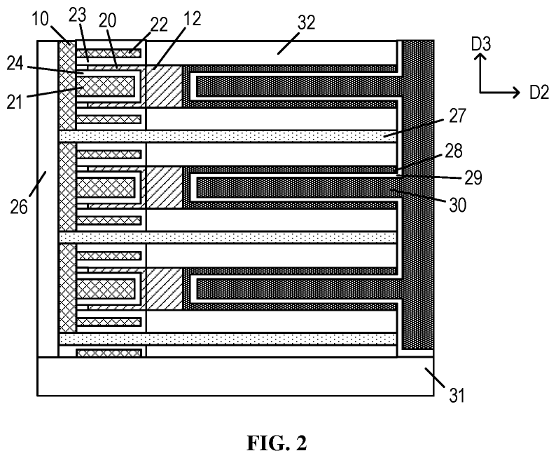

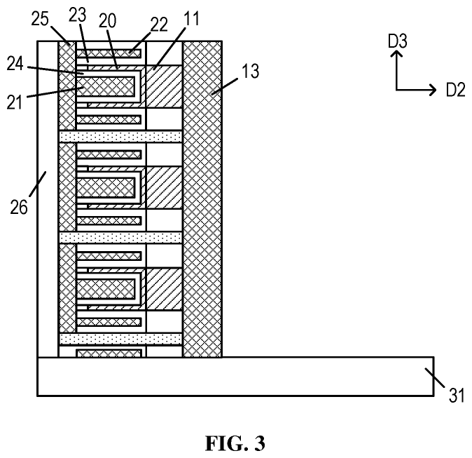

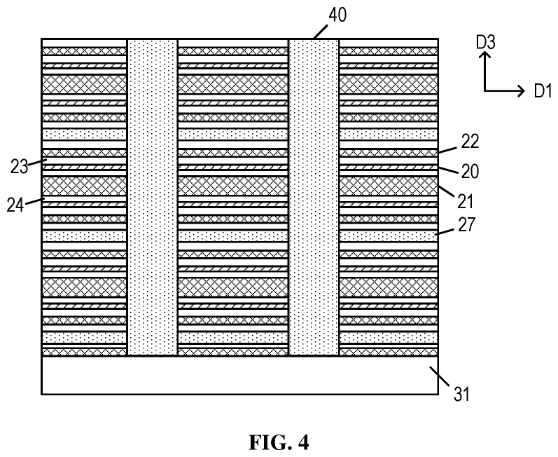

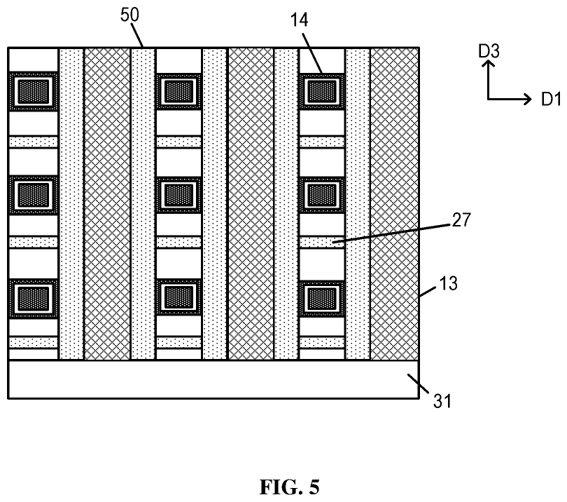

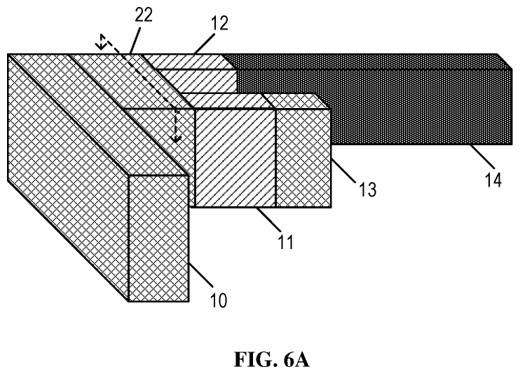

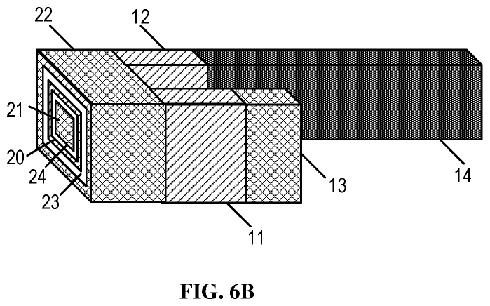

Embodiments of the disclosure provide a semiconductor structure. FIG. 1 is a schematic structural top view of a semiconductor structure in an embodiment of the disclosure; FIG. 2 is a schematic cross-sectional diagram at position a-a of FIG. 1; FIG. 3 is a schematic cross-sectional diagram at position b-b of FIG. 1; FIG. 4 is a schematic cross-sectional diagram at position c-c of FIG. 1; FIG. 5 is a schematic cross-sectional diagram at position d-d of FIG. 1; and FIG. 6A and FIG. 6B are schematic three-dimensional structural diagrams of a memory unit in an embodiment of the disclosure.

As shown in FIG. 1 to FIG. 6A and FIG. 6B, the semiconductor structure includes a substrate 31 and a stack structure located on the substrate 31. The stack structure includes a plurality of memory units MUs arranged at intervals in a first direction D1. Each of the memory units includes a transistor structure. The transistor structure includes an active structure and a gate layer. At least part of the active structure is distributed around a periphery of part of the gate layer, and a projection of the active structure on a top surface of the substrate 31 is in the shape of a U which opens toward a second direction D2. Both the first direction D1 and the second direction D2 are parallel to the top surface of the substrate 31, and the first direction D1 intersects with the second direction D2.

The semiconductor structure may be, but is not limited to DRAM. As an example, the embodiments of the disclosure are illustrated with the semiconductor structure being the DRAM. Specifically, the substrate 31 may be, but is not limited to a silicon substrate. As an example, the embodiments of the disclosure are illustrated with the substrate 31 being the silicon substrate. In other embodiments, the substrate 31 may be a substrate of gallium nitride, gallium arsenide, gallium carbide, silicon carbide, SOI or other semiconductors. The substrate 31 is configured to support device structures thereon. The plurality of memory units are arranged at intervals in the first direction D1 on the top surface of the substrate 31. When reference is made to that the projection of the active structure on the top surface of the substrate 31 is in the shape of a U which opens toward the second direction D2, it means that the contour of the projection of the active structure on the top surface of the substrate 31 is in the shape of a U, and the opening of the U shape is toward the second direction. The active structure includes a channel layer, and a source region and a drain region that are located on a same side of the channel layer. According to the embodiments of the disclosure, the active structure having the U shape is provided and further the active structure is distributed around the periphery of the gate layer, such that the transistor structure including a channel-all-around structure is formed. As a result, the power consumption of the semiconductor structure is reduced, while the control capability on the gate of the transistor structure is improved, thereby improving the electrical performance of the semiconductor structure. The top surface of the substrate 31 refers to a surface of the substrate 31 facing the stack structure. When reference is made to “a plurality of” in the embodiments of the disclosure, it refers to at least two. The first direction D1 and the second direction D2 may intersect with each other perpendicularly or obliquely. As an example, the embodiments of the disclosure are described with the first direction D1 and the second direction D2 intersecting with each other perpendicularly.

In some embodiments, the gate layer includes a first gate layer 21 and a second gate layer 22. Part of the active structure is distributed around a periphery of the first gate layer 21. The second gate layer 22 is distributed at least around a periphery of part of the active structure, and the first gate layer 21 is electrically connected to the second gate layer 22.

Specifically, the gate layer includes the first gate layer 21 and the second gate layer 22 electrically connected to each other. The part of the active structure includes a channel layer 20 and is distributed around a periphery of the first gate layer 21 to form a channel-all-around structure. The second gate layer 22 is distributed around a periphery of the part of the active structure to form a gate-all-around structure, as shown in FIG. 6B. As a result, the transistor structure in the embodiments of the disclosure has both the gate-all-around structure and the channel-all-around structure, thereby further improving the control capability on the gate of the transistor structure, simplifying the operation for controlling the memory unit and further improving the electrical performance of the semiconductor structure. FIG. 6B shows a schematic cross-sectional diagram at a dotted arrow position of FIG. 6A.

In some embodiments, the semiconductor structure further includes a word line 10.

The word line 10 extends in the first direction D1 and is electrically connected to the first gate layer 21 and the second gate layer 22 in each of the plurality of memory units arranged at intervals in the first direction D1.

Specifically, the word line 10 extends in the first direction D1, that is, the semiconductor structure has a horizontal word line structure. The first gate layer 21 and the second gate layer 22 located in a same memory unit MU are electrically connected via the word line 10, and the word line 10 electrically connects the first gate layers 21 and the second gate layers 22 in the plurality of memory units MUs arranged at intervals in the first direction D1 to simultaneously transmit control signals to the first gate layers 21 and the second gate layers 22 in the plurality of memory units MUs via the word line 10.

In order to simplify an operation for connecting the first gate layer 21 and the second gate layer 22 in the memory unit MU and to simplify the forming process of the word line 10, in some embodiments, the word line 10 is located at an end of the memory unit MU in the second direction D2, and is in contact with and electrically connected to an end of the first gate layer 21 in the second direction D2 and an end of the second gate layer 22 in the second direction D2.

Specifically, as shown in FIG. 6A, the word line 10 is located at the end of the memory unit MU in the second direction D2, and the thickness of the word line 10 in a third direction D3 is greater than or equal to the thickness of the transistor structure in the third direction D3, so that the word line 10 can be sufficiently in contact with and electrically connected to the first gate layer 21 and the second gate layer 22 in the transistor structure, and the connection stability between the word line 10 and the first gate layer 21 and the second gate layer 22 is improved, thereby further improving the yield of semiconductor structures. In an embodiment, as shown in FIG. 2 and FIG. 3, a top surface of the word line 10 in the third direction D3 is higher than top surfaces of the second gate layers 22, and a bottom surface of the word line 10 in the third direction D3 is lower than bottom surfaces of the second gate layers 22, that is, the word line 10 protrudes from the second gate layers 22 in the third direction D3, in which the third direction D3 is perpendicular to the top surface of the substrate 31.

In an embodiment, as shown in FIG. 1, gate layers of the plurality of memory units MUs arranged at intervals in the first direction D1 are independent from each other to simplify the forming process of the gate layers. In another embodiment, the second gate layers 22 of the plurality of memory units MUs arranged at intervals in the first direction D1 are connected (e.g. by a selective deposition process), thereby simplifying the forming process of the word line 10.

In some embodiments, the active structure includes a channel layer 20, a source region 11 and a drain region 12.

The channel layer 20 extends in the first direction D1, in which the channel layer 20 is distributed around the periphery of the first gate layer 21, and the second gate layer 22 is distributed around a periphery of the channel layer 20.

The source region 11 protrudes in the second direction D2 from a side surface of the channel layer 20 facing away from the word line 10.

The drain region 12 protrudes in the second direction D2 from the side surface of the channel layer 20 facing away from the word line 10, in which the source region 11 and the drain region 12 are spaced at opposite ends in the first direction D1 on the side surface of the channel layer 20 facing away from the word line 10.

Specifically, the active structure includes the channel layer 20, and the source region 11 and the drain region 12 located on a same side of the channel layer 20 in the second direction D2. Both the source region 11 and the drain region 12 are connected to the channel layer 20 and are spaced at the opposite ends of the channel layer 20 in the first direction D1, so that the projection, on the top surface of the substrate 31, of an entirety formed by the channel layer 20, the source region 11 and the drain region 12 together is in the shape of a U which opens toward the second direction D2. In an embodiment, the source region 11 and the drain region 12 are arranged in alignment in the first direction D1. For example, a first axis of the source region 11 is aligned with a second axis of the drain region 12 in the first direction D1, in which the first axis passes through the center of the source region 11 and extends in the first direction D1, and the second axis passes through the center of the drain region 12 and extends in the first direction D1.

In some embodiments, the transistor structure further includes a first gate dielectric layer 24, a second gate dielectric layer 23 and a first insulating dielectric layer.

The first gate dielectric layer 24 is located between the first gate layer 21 and the channel layer 20.

The second gate dielectric layer 23 is located between the second gate layer 22 and the channel layer 20, in which the thickness of the first gate dielectric layer 24 in a third direction D3 is less than or equal to the thickness of the second gate dielectric layer 23 in the third direction D3, in which the third direction D3 is perpendicular to the top surface of the substrate 31.

The first insulating dielectric layer is located between the word line 10 and the channel layer 20.

The thickness of the first gate dielectric layer 24 in the third direction D3 is a distance in the third direction D3 between an inner surface of the first gate dielectric layer 24 facing the first gate layer 21 and an outer surface of the first gate dielectric layer 24 facing away from the first gate layer 21. The thickness of the second gate dielectric layer 23 in the third direction D3 is a distance in the third direction D3 between an inner surface of the second gate dielectric layer 23 facing the channel layer 20 and an outer surface of the second gate dielectric layer 23 facing away from the channel layer 20. According to the embodiments of the disclosure, the thickness of the first gate dielectric layer 24 in the third direction D3 is set to be less than or equal to the thickness of the second gate dielectric layer 23 in the third direction D3. On the one hand, reducing the thickness of the first gate dielectric layer 24 can avoid that the size of the channel layer 20 is too large, thereby improving the channel performance of the transistor structure. On the other hand, increasing the thickness of the second gate dielectric layer 23 can increase the distance between the first gate layer 21 and the second gate layer 22, thereby reducing the mutual influence between the first gate layer 21 and the second gate layer 22. In an embodiment, the material of the first gate dielectric layer 24 and the material of the second gate dielectric layer 23 are the same. For example, both are an oxide material (e.g. silicon dioxide).

In order to further improve the control capability on the gate of the transistor structure while the size of the channel layer 20 is further reduced, in some embodiments, the thickness of the first gate layer 21 in a third direction D3 is greater than or equal to the thickness of the second gate layer 22 in the third direction D3, in which the third direction D3 is perpendicular to the top surface of the substrate 31. The thickness of the second gate layer 22 in the third direction D3 is a distance in the third direction between an inner surface of the second gate layer 22 facing the channel layer 20 and an outer surface thereof facing away from the channel layer 20.

In some embodiments, the memory unit MU further includes a capacitor structure 14.

The capacitor structure 14 extends in the second direction D2 and includes a bottom electrode layer 28 in contact with and electrically connected to the drain region 12 of the transistor structure, a dielectric layer 29 covering the bottom electrode layer 28, and a top electrode layer 30 covering the dielectric layer 29. In an embodiment, the material of the bottom electrode layer 28 may be the same as the material of the top electrode layer 30. For example, both are TiN, metal tungsten or other conductive materials. The material of the dielectric layer 29 is a material having a high dielectric constant (high K). The memory unit MU also includes a capacitor isolation layer 32 covering the capacitor structure 14. The capacitor isolation layer 32 is configured to isolate adjacent capacitor structures 14 to avoid signal crosstalk between adjacent capacitor structures 14.

In some embodiments, the stack structure includes a plurality of memory layers arranged at intervals in the third direction D3. The memory layer includes the plurality of memory units MUs arranged at intervals in the first direction D1. The third direction D3 is perpendicular to the top surface of the substrate 31. The semiconductor structure further includes a bit line 13.

The bit line 13 extends in the third direction D3 and is electrically connected to source regions 11 of a plurality of memory units MUs arranged at intervals in the third direction D3.

Specifically, the stack structure includes memory units MUs and interlayer insulating layers 27 alternately stacked in the third direction D3. The interlayer insulating layer 27 is configured to electrically isolate two memory units MUs adjacent in the third direction D3. In an embodiment, the material of the interlayer insulating layer 27 may be a nitride material (e.g. silicon nitride). The bit line 13 extends in the third direction D3, and is in contact with and electrically connected to the source regions 11 of the plurality of memory units MUs arranged at intervals in the third direction D3. A plurality of bit lines 13 are arranged at intervals in the first direction D1. For example, as shown in FIG. 5, there are a plurality of capacitor structures 14 arranged at intervals in the third direction D3 between bit lines adjacent in the first direction D1. When the stack structure includes the plurality of memory layers arranged at intervals in the third direction D3, there are a plurality of word lines 10, and the plurality of word lines 10 are arranged at intervals in the third direction D3. For two word lines 10 adjacent in the third direction D3, the length in the first direction D1 of one of the two word lines 10, which is closer to the substrate 31 than the other one, is greater than the length in the first direction D1 of the other one of the two word lines 10 (i.e. one of the two word lines 10 closer to the substrate 31 protrudes from the other one of the two word lines 10 in the first direction D1), so that the plurality of word lines 10 together constitute a step-like structure. The semiconductor structure further includes a covering layer 26 located on a side surface of the stack structure and covering sidewalls of the plurality of word lines 10 arranged at intervals in the third direction D3. In an embodiment, the material of the covering layer 26 may be an oxide material (e.g. silicon dioxide).

In some embodiments, the semiconductor structure further includes first support pillars 50, second support pillars 40 and interlayer insulating layers 27.

Each of the first support pillars 50 extends in the third direction D3, and is located between the capacitor structure 14 and the bit line 13.

Each of the second support pillars 40 extends in the third direction D3, and is located between memory units MUs adjacent in the first direction D1.

Each of the interlayer insulating layers 27 is located between adjacent memory layers arranged at intervals in the third direction D3.

Specifically, the first support pillars 50 and the second support pillars 40 are configured to support the stack structure, preventing the stack structure from toppling or collapsing, thereby improving the stability of the stack structure. In an embodiment, the material of the first support pillar 50 and the material of the second support pillar 40 may be the same. For example, both are a nitride material (e.g. silicon nitride).

In some embodiments, the material of the active structure is an oxide semiconductor material. In an embodiment, the oxide semiconductor material is any one or any combination of indium oxide (In₂O₃), zinc oxide (ZnO), indium zinc oxide (IZO), indium gallium zinc oxide (IGZO), indium tin zinc oxide (IZTO) or zinc oxide nitride (ZnON). Exemplarily, the material of the active structure is IGZO.

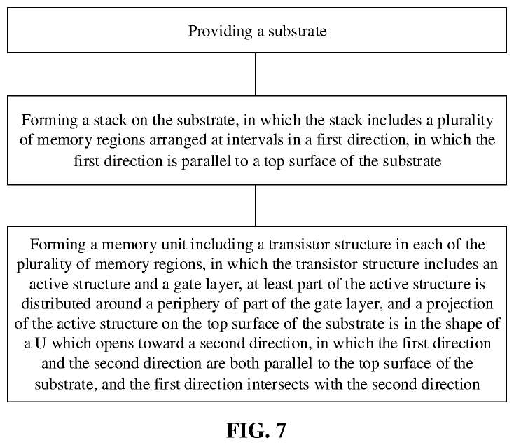

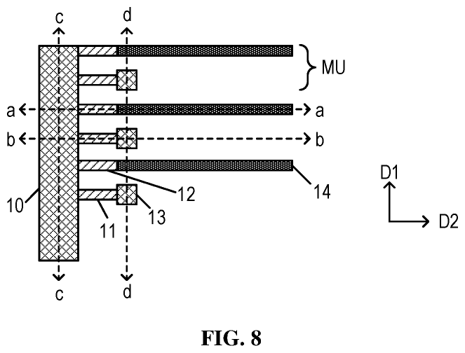

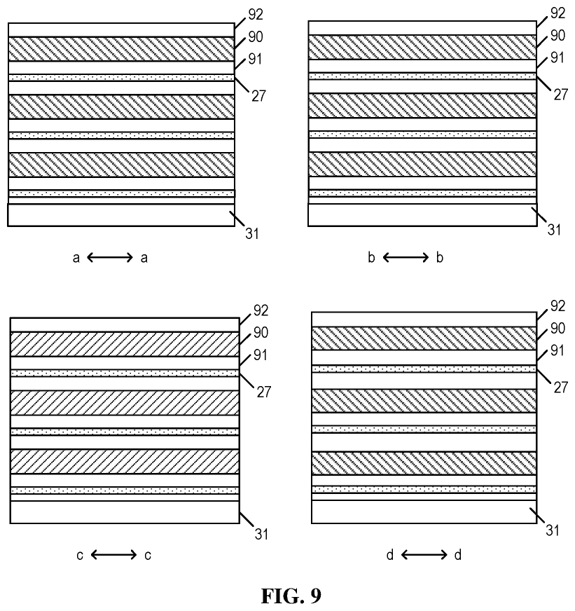

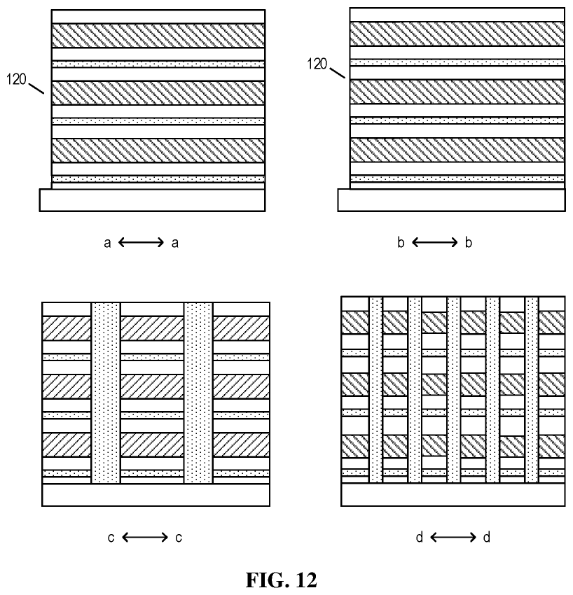

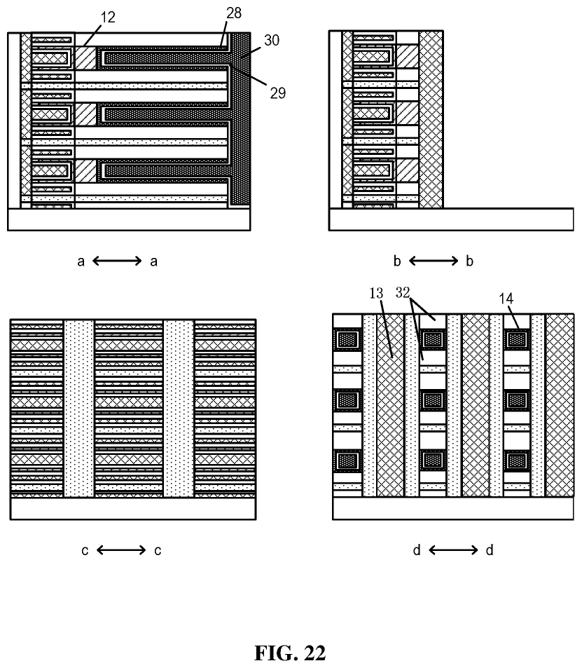

Embodiments of the disclosure also provide a method for forming a semiconductor structure. FIG. 7 is a flowchart of a method for forming a semiconductor structure in an embodiment of the disclosure. FIG. 8 to FIG. 22 are schematic structural diagrams corresponding to main operations during forming a semiconductor structure according to an embodiment of the disclosure. Herein, FIG. 8 is a schematic structural top view of a semiconductor structure formed according to an embodiment of the disclosure, and FIG. 9 to FIG. 22 are main schematic cross-sectional diagrams during forming a semiconductor structure at four positions of a-a position, b-b position, c-c position and d-d position of FIG. 8, so as to clearly show the forming process of the semiconductor structure. A schematic diagram of a semiconductor structure formed according to an embodiment of the disclosure can be seen in FIG. 1 to FIG. 6A and FIG. 6B. As shown in FIG. 1 to FIG. 22, a method for forming a semiconductor structure includes the following operations:
At S71, a substrate 31 is provided;
At S72, a stack is formed on the substrate 31. The stack includes a plurality of memory regions arranged at intervals in a first direction D1, in which the first direction D1 is parallel to a top surface of the substrate 31; and
At S73, a memory unit MU including a transistor structure is formed in each of the plurality of memory regions. The transistor structure includes an active structure and a gate layer. At least part of the active structure is distributed around a periphery of part of the gate layer, and a projection of the active structure on the top surface of the substrate 31 is in the shape of a U which opens toward a second direction D2. Both the first direction D1 and the second direction D2 are parallel to the top surface of the substrate 31, and the first direction D1 intersects with the second direction D2.

In some embodiments, the operation for forming the stack on the substrate 31 includes the following operation.

Interlayer insulating layers 27 and stack unit layers alternately stacked in a third direction D3 are formed on the substrate 31. Each of the stack unit layers includes a first isolation layer 91, a sacrificial layer 90, and a second isolation layer 92 stacked in sequence in the third direction D3, in which the third direction D3 is perpendicular to the top surface of the substrate 31, as shown in FIG. 9.

Specifically, the substrate 31 may be, but is not limited to a silicon substrate. As an example, the embodiments of the disclosure are illustrated with the substrate 31 being the silicon substrate. The interlayer insulating layers 27, the first isolation layers 91, the sacrificial layers 90, and the second isolation layers 92 may be alternately deposited on the top surface of the substrate 31 by a chemical vapor deposition process, a physical vapor deposition process, or an atomic layer deposition process to form the stack. An etching selection ratio between any two of the interlayer insulating layer 27, the first isolation layer 91, the sacrificial layer 90 and the second isolation layer 92 should be high (for example, the etching selection ratio between any two of them should be greater than 3), so as to facilitate subsequent selective etching.

In some embodiments, the materials of the first isolation layer 91 and the second isolation layer 92 are both an oxide material (e.g. silicon dioxide), the material of the sacrificial layer 90 is a polysilicon material, and the material of the interlayer insulating layer 27 is a nitride material (e.g. silicon nitride).

In some embodiments, the following operations are further included before forming the memory unit including the transistor structure in each of the plurality of memory regions.

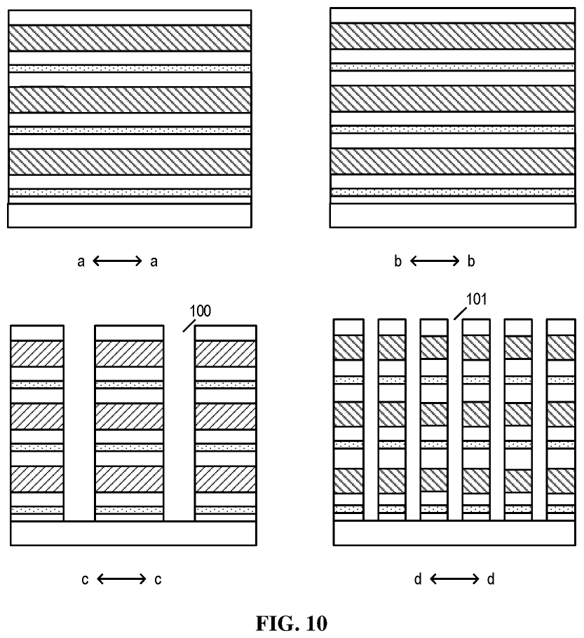

The stack is etched to form a first support trench 101 located in the memory region and a second support trench 100 located between memory regions adjacent in the first direction D1, as shown in FIG. 10.

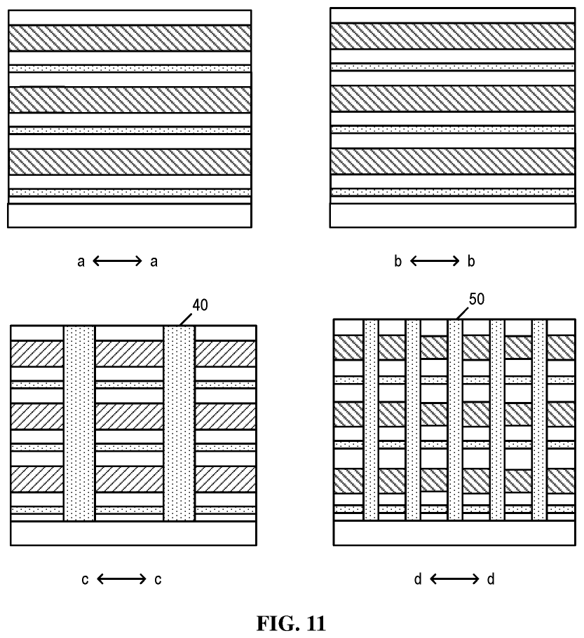

A first support pillar 50 is formed in the first support trench 101 and a second support pillar 40 is formed in the second support trench 100, as shown in FIG. 11.

Specifically, after forming the stack, the stack is etched in the third direction D3 to form the first support trench 101 and the second support trench 100. Next, an insulating dielectric material such as a nitride (for example, silicon nitride) is filled in the first support trench 101 and the second support trench 100 to form the first support pillar 50 and the second support pillar 40. On the one hand, the first support pillars 50 and the second support pillars 40 are configured to support the stack, preventing the stack from toppling or collapsing in the subsequent processes. On the other hand, the first support pillars 50 are also configured to isolate the capacitor structures and bit lines to be formed subsequently and the second support pillars 40 are also configured to isolate adjacent memory regions.

In some embodiments, each of the plurality of memory regions includes a transistor region and a capacitor region located outside the transistor region in the second direction D2. The operation for forming the memory unit including the transistor structure in each of the plurality of memory regions includes the following operations.

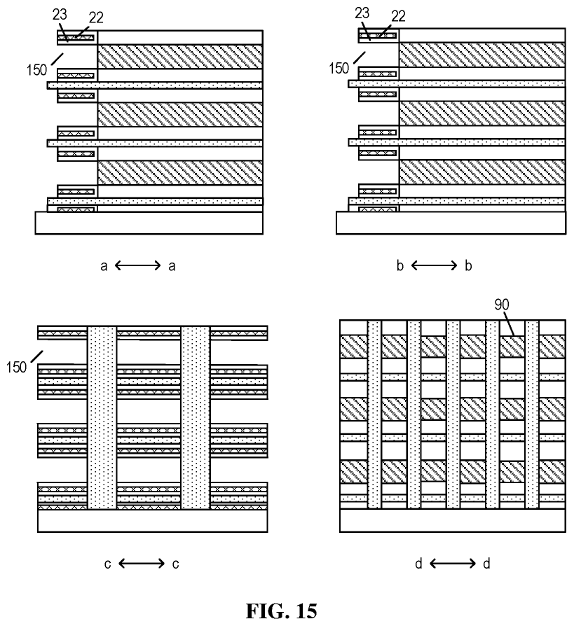

The sacrificial layer 90 in the transistor region is removed to form a first trench 150, as shown in FIG. 15.

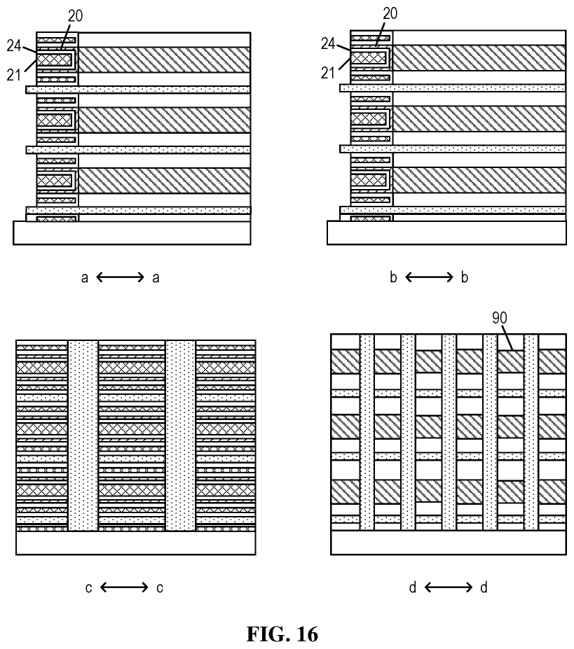

A first gate layer 21 and a channel layer 20 distributed around a periphery of the first gate layer 21 are formed in the first trench 150. The gate layer includes the first gate layer 21, and the active structure includes the channel layer 20, as shown in FIG. 16.

In some embodiments, the following operations are further included before forming the first trench 150.

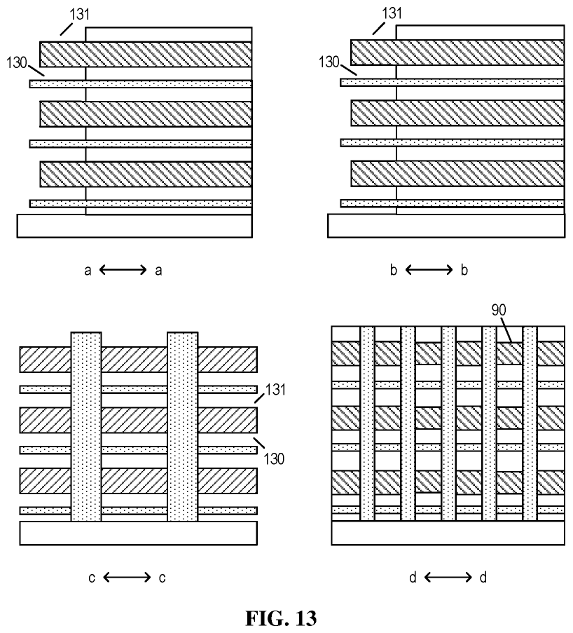

The first isolation layer 91 and the second isolation layer 92 that are located in the transistor region are removed to form a second trench 130 and a third trench 131 at opposite sides of the sacrificial layer 90 in the third direction D3 in the stack unit, as shown in FIG. 13.

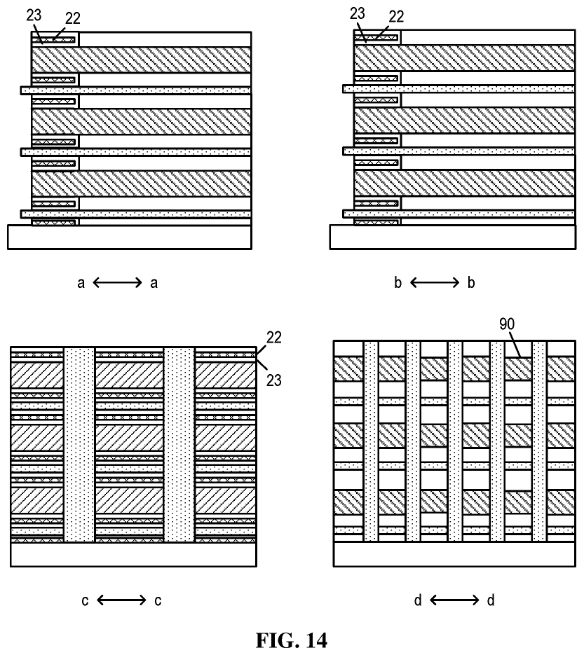

A second gate layer 22 covering the sacrificial layer 90 is formed in the second trench 130 and the third trench 131. As shown in FIG. 14, the gate layer includes the first gate layer 21 and the second gate layer 22.

In some embodiments, the specific operations for forming the second gate layer 22 covering the sacrificial layer 90 in the second trench 130 and the third trench 131 include the following operations.

A second gate dielectric layer 23 covering an inner wall of the second trench 130 and an inner wall of the third trench 131 is formed.

The second gate layer 22 covering the second gate dielectric layer 23 is formed in the second trench 130 and the third trench 131, as shown in FIG. 14.

In some embodiments, the specific operations for forming the first gate layer 21 and the channel layer 20 distributed around the periphery of the first gate layer 21 in the first trench 150 include the following operations.

The channel layer 20 covering the entire inner wall of the first trench 150 is formed.

The first gate layer 21 located on the channel layer 20 is formed in the first trench 150. A thickness of the first gate layer 21 in the third direction D3 is greater than or equal to a thickness of the second gate layer 22 in the third direction D3.

In some embodiments, the operation for forming the first gate layer 21 located on the channel layer 20 in the first trench 150 includes the following operations.

A first gate dielectric layer 24 covering the channel layer 20 is formed in the first trench 150. A thickness of the first gate dielectric layer 24 in the third direction D3 is less than or equal to a thickness of the second gate dielectric layer 23 in the third direction D3.

The first gate layer 21 covering the first gate dielectric layer 24 is formed in the first trench 150.

Specifically, the stack further includes an isolation region located outside the transistor region in the second direction D2, and the isolation region and the capacitor region are distributed on opposite sides of the transistor region in the second direction D2. After forming the first support pillar 50 and the second support pillar 40, the stack in the isolation region may be removed by an etching process to form an isolation trench 120 exposing the substrate 31. Thereafter, part of the first isolation layer 91 and part of the second isolation layer 92 located in the transistor region may be removed from the isolation trench 120 by a lateral etching process to form the second trench 130 located under the sacrificial layer 90 and a third trench 131 located above the sacrificial layer 90 in the memory region, as shown in FIG. 13.

Next, an insulating dielectric material such as an oxide (for example, silicon dioxide) may be deposited in the second trench 130 and the third trench 131 along the second trench 130 and the third trench 131 by an atomic layer deposition process to form the second gate dielectric layer 23 covering the entire inner wall of the second trench 130 and the entire inner wall of the third trench 131. Thereafter, a conductive material such as TiN is deposited in the second trench 130 and the third trench 131 along the second trench 130 and the third trench 131 by an atomic layer deposition process to form the second gate layer 22 that covers the surface of the second gate dielectric layer 23 and fills up the second trench 130 and the third trench 131, as shown in FIG. 14. Then, part of the sacrificial layer 90 in the transistor region may be removed from the isolation trench 120 by a lateral etching process to form the first trench 150, as shown in FIG. 15. Thereafter, the channel layer 20 covering the entire inner wall of the first trench 150, the first gate dielectric layer 24 covering the surface of the channel layer 20, and the first gate layer 21 covering the surface of the first gate dielectric layer 24 and filling up the first trench 150 are formed in the first trench 150 in sequence, as shown in FIG. 16.

The thickness of the first gate dielectric layer 24 in the third direction D3 is a distance in the third direction D3 between an inner surface of the first gate dielectric layer 24 facing the first gate layer 21 and an outer surface of the first gate dielectric layer 24 facing away from the first gate layer 21. The thickness of the second gate dielectric layer 23 in the third direction D3 is a distance in the third direction D3 between an inner surface of the second gate dielectric layer 23 facing the channel layer 20 and an outer surface of the second gate dielectric layer 23 facing away from the channel layer 20. The thickness of the second gate layer 22 in the third direction D3 is a distance in the third direction between an inner surface of the second gate layer 22 facing the channel layer 20 and an outer surface thereof facing away from the channel layer 20. The thickness of the first gate layer 21 in the third direction D3 is set to be greater than or equal to the thickness of the second gate layer 22 in the third direction D3, and the thickness of the first gate dielectric layer 24 in the third direction D3 is set to be less than or equal to the thickness of the second gate dielectric layer 23 in the third direction D3. By these settings, the electrical performance of the semiconductor structure can be further improved while controlling the size of the memory unit.

In some embodiments, after forming the first gate layer 21 and the channel layer 20 distributed around the periphery of the first gate layer 21 in the first trench 150, the following operation is further included.

A word line 10 extending in the first direction D1 is formed on the substrate 31. The word line 10 is electrically connected to the first gate layer 21 and the second gate layer 22 in each of a plurality of memory units arranged at intervals in the first direction D1.

In some embodiments, the operation for forming the word line 10 extending in the first direction D1 on the substrate 31 includes the following operations.

Part of the channel layer 20 is removed in the second direction D2 to form a fourth trench.

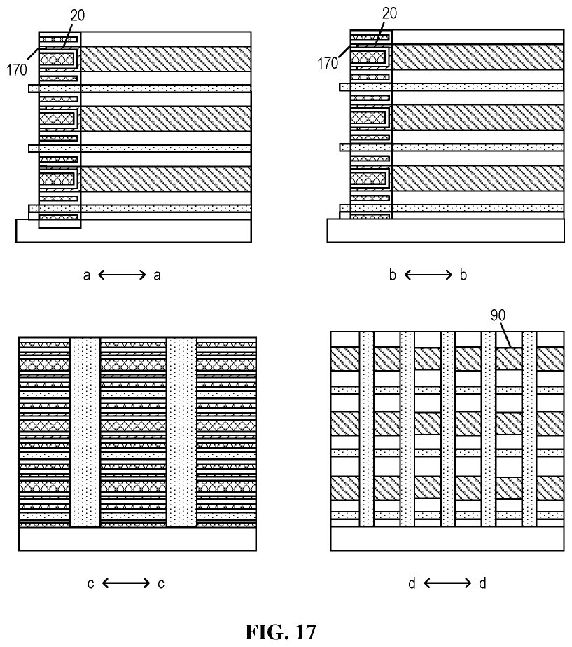

A first insulating dielectric layer 170 is formed in the fourth trench, as shown in FIG. 17.

The word line 10 extending in the first direction D1 is formed at ends of transistor structures in the second direction D2. The word line 10 is in contact with and electrically connected to ends of the first gate layers 21 in the second direction D2 and ends of the second gate layers 22 in the second direction D2.

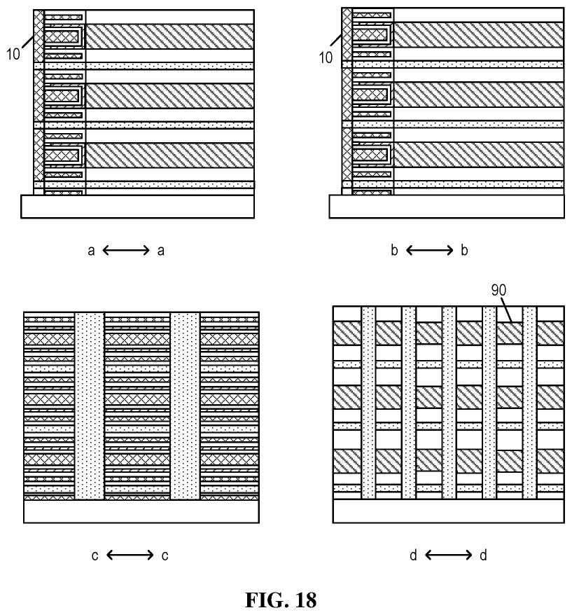

Specifically, the part of the channel layer 20 may be removed along the isolation trench 120 by a selective etching process to form the fourth trench located between the first gate dielectric layer 24 and the second gate dielectric layer 23. An insulating dielectric material such as an oxide (e.g. silicon dioxide) is deposited in the fourth trench to form the first insulating dielectric layer 170. Next, part of the first gate dielectric layer 24, part of the second gate dielectric layer 23, and part of the first insulating dielectric layer 170 in the memory region are removed along the isolation trench 120 to form a word line trench located between adjacent interlayer insulating layers 27. A conductive material such as TiN is deposited in the word line trench by an atomic layer deposition process to form the word line 10, which connects the first gate layers 21 and the second gate layers 22 and extends in the first direction D1, as shown in FIG. 18. The remaining first insulating dielectric layer 170 is configured to electrically isolate the word line 10 from the channel layer 20.

In some embodiments, the memory region further includes a capacitor region and a bit line region located on a same side of the transistor region in the second direction D2, and the capacitor region and the bit line region are arranged at intervals in the first direction D1. After forming the word line 10 extending in the first direction D1 on the substrate 31, the following operations are further included.

The stack in the bit line region and part of the sacrificial layer 90 in the transistor region are removed to form a fifth trench 200 located in the bit line region and a source trench located in the transistor region, respectively. The source trench exposes an end of the channel layer 20 in the second direction D2.

A source region 11 in contact with and electrically connected to the channel layer 20 is formed in the source trench.

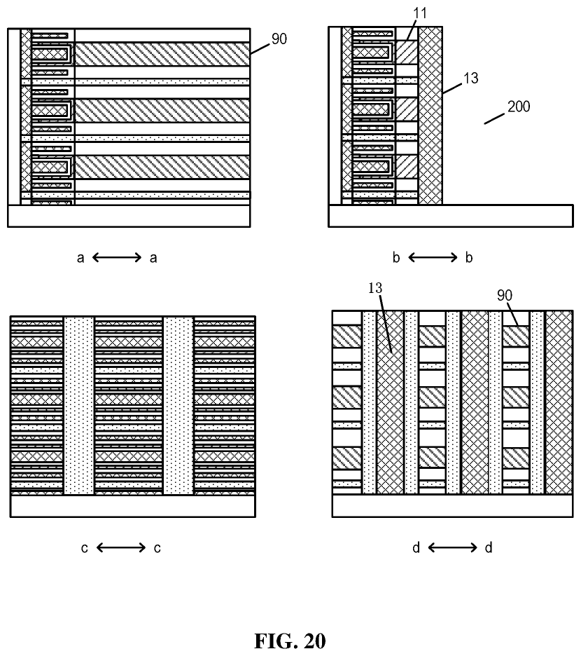

A bit line 13 in contact with and electrically connected to source regions 11 is formed in fifth trench 200, as shown in FIG. 20.

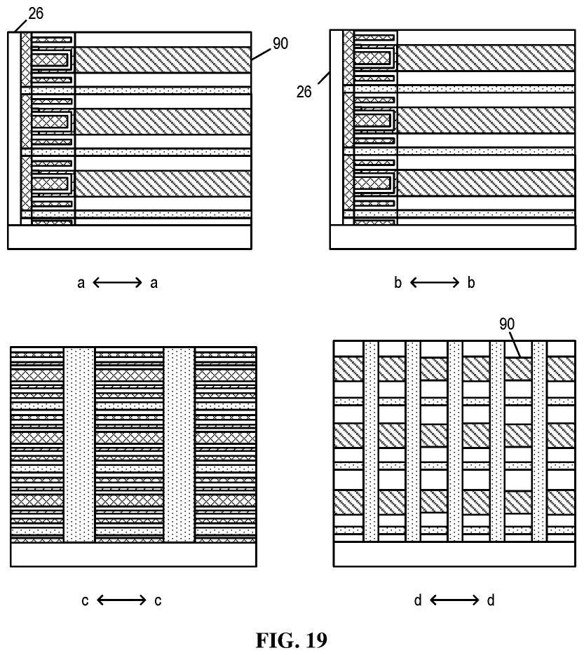

Specifically, an insulating dielectric material such as an oxide (e.g. silicon dioxide) is deposited in the isolation trench 120 to form a covering layer 26, as shown in FIG. 19, so as to avoid any influence of the subsequent processes on the word line 10. Thereafter, the stack in the bit line region is removed by an etching process to form the fifth trench 200 exposing the substrate 31. Part of the sacrificial layer 90 in the transistor region is removed along the fifth trench 200 to form the source trench in communication with the fifth trench 200. Next, the source region 11 that fills up the source trench and is in contact with the channel layer 20 is formed, and a bit line 13 extending in the third direction D3 is formed in the fifth trench 200, and the bit line 13 is continuously in contact with and electrically connected to a plurality of source regions 11 arranged at intervals in the third direction D3, as shown in FIG. 20. In an embodiment, the material of the bit line 13 is a conductive material such as metal tungsten.

In some embodiments, after forming the word line 10 extending in the first direction D1 on the substrate 31, the following operations are further included.

The sacrificial layer 90 in the capacitor region and the sacrificial layer 90 retained in the transistor region are removed to form a capacitor trench located in the capacitor region and a drain trench located in the transistor region, respectively. The drain trench exposes an end of the channel layer 20 in the second direction D2.

A drain region 12 in contact with and electrically connected to the channel layer 20 is formed in the drain trench.

A capacitor structure 14 in contact with and electrically connected to the drain region 12 is formed in the capacitor trench.

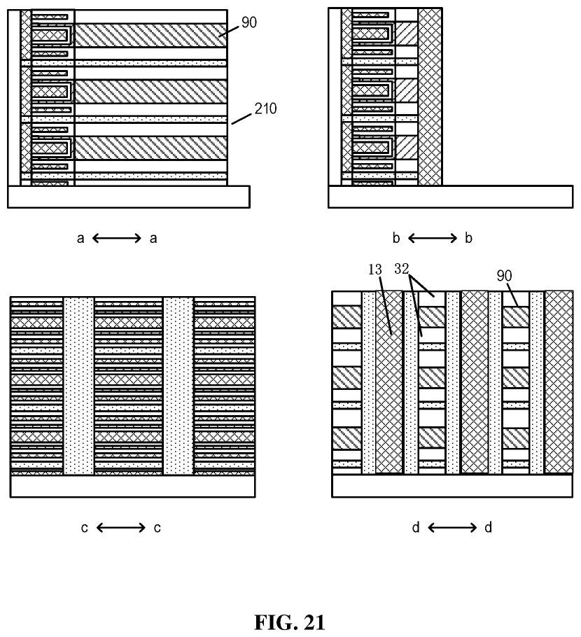

Specifically, part of the stack on a side of the capacitor region away from the transistor region is removed to form a sixth trench 210 exposing the substrate 31, as shown in FIG. 21. The sacrificial layer 90 in the capacitor region and the sacrificial layer 90 retained in the transistor region are removed along the sixth trench 210 to form the capacitor trench located in the capacitor region and the drain trench located in the transistor region. The capacitor trench communicates with the drain trench. Then, a drain region 12 that fills up the drain trench and is in contact with and connected to the channel layer 20 is formed in the drain trench, and a capacitor structure 14 that is in contact with and electrically connected to the drain region 12 is formed in the capacitor trench. The capacitor structure 14 includes a bottom electrode layer 28 in contact with and electrically connected to the drain region 12 of the transistor structure, a dielectric layer 29 covering the bottom electrode layer 28, and a top electrode layer 30 covering the dielectric layer 29. The first isolation layer 91 and the second isolation layer 92 retained in the capacitor region together serve as the capacitor isolation layer 32. In embodiments of the disclosure, a bit line 13 may be formed first, and then capacitor structures 14 may be formed. Alternatively, capacitor structures 14 may be formed first, and then a bit line 13 is formed. Those skilled in the art can choose according to the actual needs.

In some embodiments, the material of the active structure is an oxide semiconductor material. For example, the materials of the channel layer 20, the source region 11 and the drain region 12 of the active structure are all an oxide semiconductor material. In an embodiment, the oxide semiconductor material is any one or any combination of indium oxide (In₂O₃), zinc oxide (ZnO), indium zinc oxide (IZO), indium gallium zinc oxide (IGZO), indium tin zinc oxide (IZTO) or zinc oxide nitride (ZnON). Exemplarily, the material of the active structure is IGZO.

According to the semiconductor structure and the method for forming the same provided by some embodiments of the disclosure, at least part of the active structure of the transistor structure is distributed around the periphery of the gate layer, such that the channel-all-around transistor structure is formed. Moreover, the active structure of the transistor structure is set to be in the shape of a U extending in the direction parallel to the top surface of the substrate (e.g. the second direction). By these settings, the power consumption of the semiconductor structure is reduced while the control capability on the gate of the transistor structure is improved, thereby improving the electrical performance of the semiconductor structure. In addition, according to some embodiments of the disclosure, the channel layer is formed by removing the sacrificial layer in the stack during forming the semiconductor structure. As a result, it is not necessary to form a channel layer by an epitaxial growth process and a doping process that are complex. Therefore, the manufacturing process of the semiconductor structure is simplified, and it is helpful to increase the stack height of the stack structure in the semiconductor structure and improve the manufacturing yield of semiconductor structures.

The foregoing are only exemplary embodiments of the disclosure. It should be noted that some modifications and variations may be made by those skilled in the art without departing from the principles of the disclosure. Such modifications and variations should also be considered within the protection scope of the disclosure.

1. A semiconductor structure, comprising:
a substrate; and
a stack structure located on the substrate, the stack structure comprising a plurality of memory units arranged at intervals in a first direction, each of the plurality of memory units comprising a transistor structure, the transistor structure comprising an active structure and a gate layer, at least part of the active structure being distributed around a periphery of part of the gate layer, a projection of the active structure on a top surface of the substrate being in a shape of a U which opens toward a second direction, wherein both the first direction and the second direction are parallel to the top surface of the substrate, and the first direction intersects with the second direction.

2. The semiconductor structure according to claim 1, wherein the gate layer comprises:
a first gate layer, the part of the active structure being distributed around a periphery of the first gate layer; and
a second gate layer, the second gate layer being distributed at least around a periphery of the part of the active structure, and the first gate layer being electrically connected to the second gate layer.

3. The semiconductor structure according to claim 2, further comprising:
a word line extending in the first direction and being electrically connected to the first gate layer and the second gate layer in each of the plurality of memory units arranged at intervals in the first direction,
wherein the word line is located at ends of the plurality of memory units in the second direction, and is in contact with and electrically connected to an end of the first gate layer in the second direction and an end of the second gate layer in the second direction in each of the plurality of memory units.

4. The semiconductor structure according to claim 3, wherein the active structure comprises:
a channel layer extending in the first direction, the channel layer being distributed around the periphery of the first gate layer, and the second gate layer being distributed around a periphery of the channel layer;
a source region protruding in the second direction from a side surface of the channel layer facing away from the word line; and
a drain region protruding in the second direction form the side surface of the channel layer facing away from the word line, and the source region and the drain region being spaced at opposite ends of the channel layer in the first direction.

5. The semiconductor structure according to claim 4, wherein the transistor structure further comprises:
a first gate dielectric layer located between the first gate layer and the channel layer;
a second gate dielectric layer located between the second gate layer and the channel layer, and a thickness of the first gate dielectric layer in a third direction being less than or equal to a thickness of the second gate dielectric layer in the third direction, wherein the third direction is perpendicular to the top surface of the substrate; and
a first insulating dielectric layer located between the word line and the channel layer.

6. The semiconductor structure according to claim 2, wherein a thickness of the first gate layer in a third direction is greater than or equal to a thickness of the second gate layer in the third direction, wherein the third direction is perpendicular to the top surface of the substrate.

7. The semiconductor structure according to claim 4, wherein the memory unit further comprises:
a capacitor structure extending in the second direction and comprising a bottom electrode layer in contact with and electrically connected to the drain region of the transistor structure, a dielectric layer covering the bottom electrode layer, and a top electrode layer covering the dielectric layer.

8. The semiconductor structure according to claim 7, wherein the stack structure comprises a plurality of memory layers arranged at intervals in a third direction, each of the plurality of memory layers comprising the plurality of memory units arranged at intervals in the first direction, wherein the third direction is perpendicular to the top surface of the substrate; and the semiconductor structure further comprises:
a bit line extending in the third direction and being electrically connected to source regions of a plurality of memory units arranged at intervals in the third direction.

9. The semiconductor structure according to claim 8, further comprising:
first support pillars extending in the third direction, and each of the first support pillars being located between the capacitor structure and the bit line;
second support pillars extending in the third direction, and each of the second support pillars being located between memory units adjacent in the first direction; and
interlayer insulating layers, each of the interlayer insulating layers being located between adjacent memory layers arranged at intervals in the third direction.

10. A method for forming a semiconductor structure, comprising:
providing a substrate;
forming a stack on the substrate, wherein the stack comprises a plurality of memory regions arranged at intervals in a first direction, wherein the first direction is parallel to a top surface of the substrate; and
forming a memory unit comprising a transistor structure in each of the plurality of memory regions, wherein the transistor structure comprises an active structure and a gate layer, at least part of the active structure is distributed around a periphery of part of the gate layer, and a projection of the active structure on the top surface of the substrate is in a shape of a U which opens toward a second direction, wherein the first direction and the second direction are both parallel to the top surface of the substrate, and the first direction intersects with the second direction.

11. The method according to claim 10, wherein the forming the stack on the substrate comprises:
forming interlayer insulating layers and stack unit layers alternately stacked in a third direction on the substrate, wherein each of the stack unit layers comprises a first isolation layer, a sacrificial layer, and a second isolation layer stacked in sequence in the third direction, wherein the third direction is perpendicular to the top surface of the substrate.

12. The method according to claim 11, further comprising, before forming the memory unit comprising the transistor structure in each of the plurality of memory regions,
etching the stack to form a first support trench located in the memory region and a second support trench located between memory regions adjacent in the first direction; and
forming a first support pillar in first support trench, and forming a second support pillar in the second support trench.

13. The method according to claim 11, wherein the memory region comprises a transistor region and a capacitor region located outside the transistor region in the second direction; and the forming the memory unit comprising the transistor structure in each of the plurality of memory regions comprises:
forming a first trench by removing the sacrificial layer in the transistor region; and
forming a first gate layer and a channel layer distributed around a periphery of the first gate layer in the first trench, wherein the gate layer comprises the first gate layer, and the active structure comprises the channel layer,
wherein the method further comprises, before forming the first trench,
forming a second trench and a third trench at opposite sides of the sacrificial layer in the third direction in the stack, by removing the first isolation layer and the second isolation layer in the transistor region; and
forming a second gate layer covering the sacrificial layer in the second trench and the third trench, wherein the gate layer comprises the first gate layer and the second gate layer.

14. The method according to claim 13, wherein the forming the second gate layer covering the sacrificial layer in the second trench and the third trench comprises:
forming a second gate dielectric layer covering an inner wall of the second trench and an inner wall of the third trench; and
forming the second gate layer covering the second gate dielectric layer in the second trench and the third trench.

15. The method according to claim 14, wherein the forming the first gate layer and the channel layer distributed around the periphery of the first gate layer in the first trench comprises:
forming the channel layer covering an entire inner wall of the first trench; and
forming the first gate layer located on the channel layer in the first trench, wherein a thickness of the first gate layer in the third direction is greater than or equal to a thickness of the second gate layer in the third direction.

16. The method according to claim 15, wherein the forming the first gate layer located on the channel layer in the first trench comprises:
forming a first gate dielectric layer covering the channel layer in the first trench, wherein a thickness of the first gate dielectric layer in the third direction is less than or equal to a thickness of the second gate dielectric layer in the third direction; and
forming the first gate layer covering the first gate dielectric layer in the first trench.

17. The method according to claim 13, further comprising, after forming the first gate layer and the channel layer distributed around the periphery of the first gate layer in the first trench,
forming a word line extending in the first direction on the substrate, wherein the word line is electrically connected to the first gate layer and the second gate layer in the memory unit formed in each of the plurality of memory regions arranged at intervals in the first direction.

18. The method according to claim 17, wherein the forming the word line extending in the first direction on the substrate comprises:
forming a fourth trench by removing part of the channel layer in the second direction;
forming a first insulating dielectric layer in the fourth trench; and
forming the word line extending in the first direction at an end of the transistor structure in the second direction, and the word line is in contact with and electrically connected to an end of the first gate layer in the second direction and an end of the second gate layer in the second direction.

19. The method according to claim 17, wherein the memory region further comprises a capacitor region and a bit line region located on a same side of the transistor region in the second direction, the capacitor region and the bit line region are arranged at intervals in the first direction; and the method further comprises, after forming the word line extending in the first direction on the substrate,
forming a fifth trench located in the bit line region and a source trench located in the transistor region, by removing the stack in the bit line region and removing part of the sacrificial layer in the transistor region, wherein the source trench exposes an end of the channel layer in the second direction;
forming a source region in contact with and electrically connected to the channel layer in the source trench; and
forming a bit line in contact with and electrically connected to the source region in the fifth trench.

20. The method according to claim 19, further comprising, after forming the word line extending in the first direction on the substrate,
forming a capacitor trench located in the capacitor region and a drain trench located in the transistor region, by removing the sacrificial layer in the capacitor region and removing the sacrificial layer retained in the transistor region, wherein the drain trench and the capacitor trench communicate with each other and expose an end of the channel layer in the second direction;
forming a drain region in contact with and electrically connected to the channel layer in the drain trench; and
forming a capacitor structure in contact with and electrically connected to the drain region in the capacitor trench.
